(19) United States
(12) Patent Application Publication
(10) Pub. No.: US 2018/0249599 A1
(43) Pub. Date: Aug. 30, 2018

(54) CURVED SHIELD ON A CIRCUIT BOARD

(71) Applicant: 3M INNOVATIVE PROPERTIES COMPANY, St. Paul, MN (US)

(72) Inventors: Jin-Bae Kim, Gyounggoi-do (KR); Jung-Ju Suh, Seoul (KR); Jeongwan Choi, Kyonggi-Do (KR)

(21) Appl. No.: 15/755,207

(22) PCT Filed: Sep. 19, 2016
(86) PCT No.: PCT/US2016/052417

§ 371 Date: Feb. 26, 2018

Related U.S. Application Data
(60) Provisional application No. 62/234,143, filed on Sep. 29, 2015.

(51) Int. Cl. H05K 9/00; H05K 1/18; H05K 1/02

(52) U.S. Cl. CPC H05K 9/0032; H05K 1/181; H05K 1/0216; H05K 2201/10522; H05K 2201/2018; H05K 2201/10371; H05K 2201/09018

(57) ABSTRACT

A system includes a curved circuit board with at least one electronic component mounted on the circuit board and electrically connected to a first electrically conductive trace of the circuit board. The system includes an electrically conductive curved fence conformably attached to the circuit board and surrounding the at least one electronic component. The fence is electrically connected to a different second electrically conductive trace of the circuit board. The system further includes an electrically conductive lid conformably attached to a top side of the fence. The electrically conductive lid covers the at least one electronic component. The fence comprises a plurality of spaced apart first tabs arranged along at least a first portion of a perimeter of the fence. Each first tab has a free end and is attached to the electrically conductive lid or the circuit board.

### TECHNICAL FIELD

This disclosure relates generally to circuit board shields in curved circuit board systems.

### BACKGROUND

Some circuit board systems include a curved design. For example, wearable electronics that are configured to fit on a human body may be curved. Other types of devices may also have a curved structure. While a circuit board may exhibit some flexibility, a shield for the circuit board may be too rigid to bend in a particular curved shape.

### BRIEF SUMMARY

Some embodiments involve a system including a curved circuit board. The system includes at least one electronic component mounted on the circuit board and electrically connected to a first electrically conductive trace of the circuit board. The system includes an electrically conductive curved fence conformably attached to the circuit board and surrounding the at least one electronic component. The fence is electrically connected to a different second electrically conductive trace of the circuit board. The system further includes an electrically conductive lid conformably attached to a top side of the fence. The electrically conductive lid covers the at least one electronic component. The fence comprises a plurality of spaced apart first tabs arranged along at least a first portion of a perimeter of the fence. Each first tab has a free end and is attached to the electrically conductive lid or the circuit board.

Some embodiments involve a flexible rectangular metal fence for conformably mounting on a curved circuit board and surrounding an electronic component mounted on the circuit board. The fence comprises opposing parallel first sides and opposing parallel second

### BRIEF DESCRIPTION OF DRAWINGS

FIG. 1 illustrates a circuit board system having shield according to some embodiments;

FIG. 2 shows a bendable circuit board system in accordance with various embodiments described herein;

FIG. 3 illustrates a more detailed view of the bendable circuit board system of FIG. 2 according to some aspects;

FIG. 4A illustrates a curved shield fence in accordance with embodiments described herein;

FIGS. 4B-4F show a first bendable shield fence according to various aspects; and

FIGS. 5A-5E show a second shield fence capable of being bent in accordance with various embodiments.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION OF ILLUSTRATIVE EMBODIMENTS

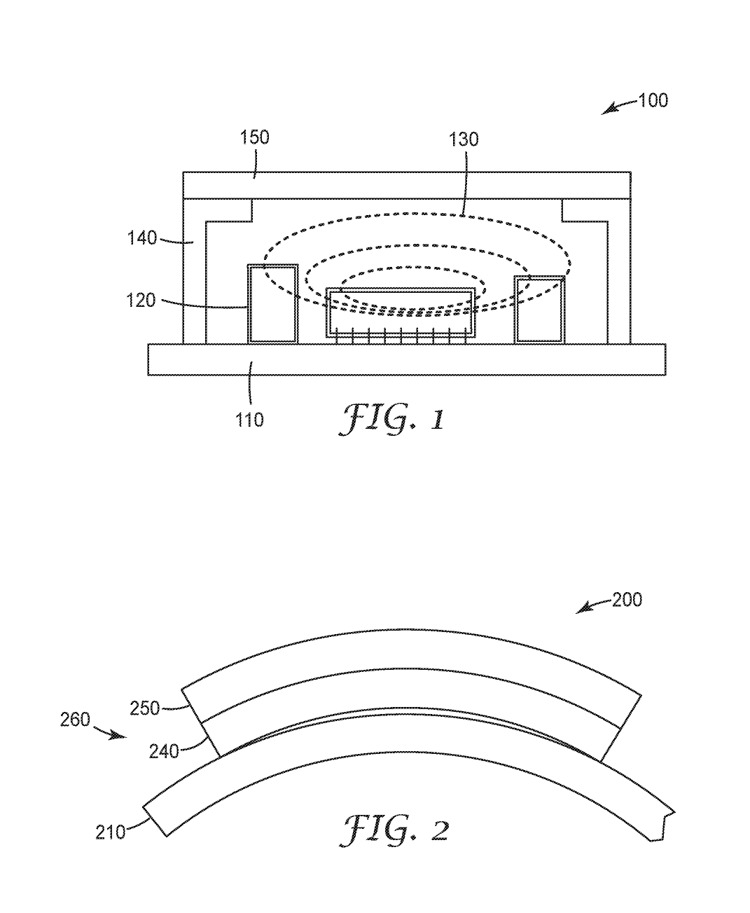

FIG. 1 illustrates a circuit board system 100 having a circuit board 110, e.g., a printed circuit board (PCB) having components 120. Electromagnetic noise 130 from the circuit board 110 may be shielded using a shield, e.g., a Controller Area Network (CAN) shield. The shield includes a shield fence portion 140 and an upper plate portion 150.

In order to create a system that is suitable to be used with bendable electronics, the shield, e.g., CAN shield) can be designed to be bendable. Bendable systems may include wearable devices such as watches, glasses. Bendable systems may also be applicable to any mobile and/or stationary devices that have a curved design. Adding slots to a shield of a circuit board may allow a circuit board to have a curved configuration.

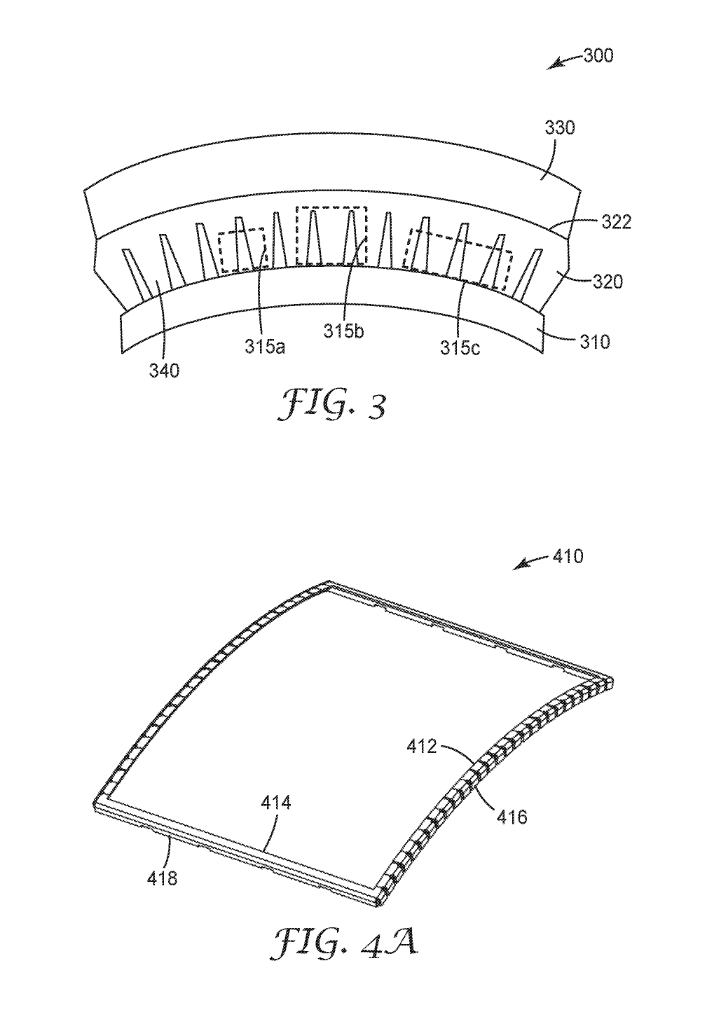

FIG. 2 illustrates a circuit board system 200 having a curved circuit board 210. The system 200 also includes shield 260 comprising a curved, bendable, and/or flexible shield fence portion 240. According to various implementations, the shield fence portion 240 comprises metal. The shield 260 includes an upper plate portion 250. The upper plate portion may comprise a stretchable and/or flexible conductive lid tape. The lid tape may include an acrylic adhesive. The lid tape may be a conductive non-woven tape and/or may comprise conductive particles, for example.

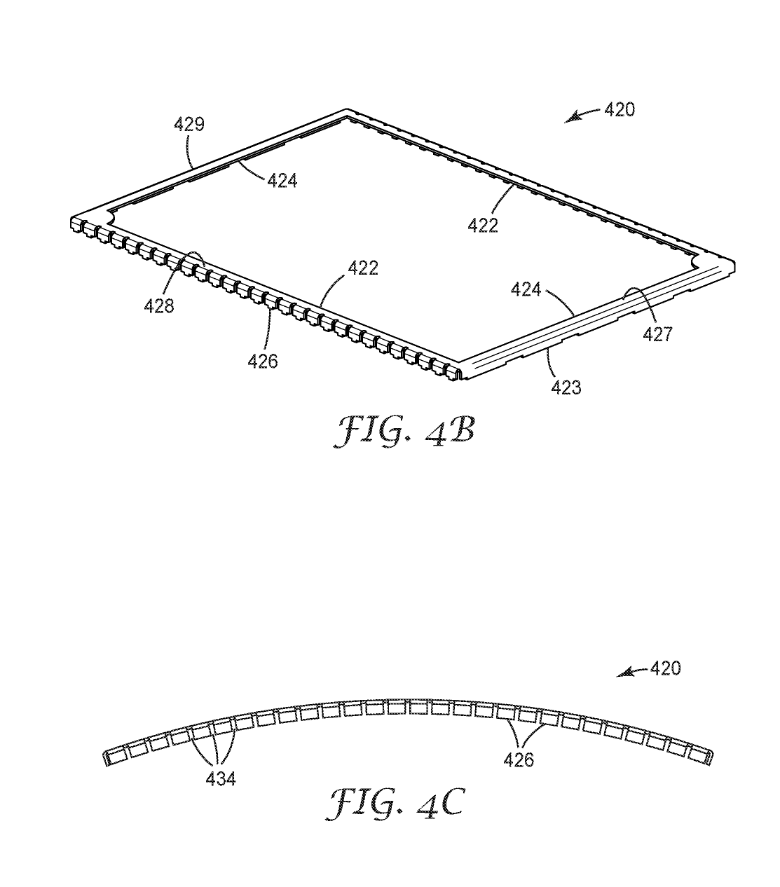

FIG. 3 illustrates a portion of a circuit board system 300 that includes a curved circuit board 310. In some cases, the curved circuit board is rigid. The curved circuit board may be capable of being bent into the curved shape and/or the circuit board may be flexible. The curved circuit board 310 may have the shape of a partial cylinder, for example. The curved circuit board 310 has at least one electronic component 315a, 315b, 315c disposed on the circuit board 310. While FIG. 3 illustrates three electronic components, it is to be understood that a circuit board system can include more or fewer electronic components on the circuit board. The electronic components 315a, 315b, 315c are mounted on the circuit board 310 and are electrically connected to at least a first electrically conductive trace of the circuit board 310.

An electrically conductive curved fence 320 is conformably attached to the circuit board 310 and surrounds at least one electronic component 315a, 315b, 315c. The electrically conductive fence may surround all of the electronic components on the circuit board or a portion of the electronic components on the circuit board. The fence 320 may be electrically connected to at least a second electrically conductive trace of the circuit board 310. The second electrically conductive trace may be different than the first electrically conductive trace. The fence 320 includes a plurality of spaced apart first tabs 340 that are arranged along at least a first portion of a perimeter of the shield fence 320.

An electrically conductive lid 330 is conformably attached to a top side 322 of the shield fence 320. The electrically conductive lid 330 covers at least one of the electronic components 315a, 315b, 315c. According to various implementations, the fence 320 surrounds all of the electronic components on the circuit board 310 and the electrically conductive lid covers all of the electronic components of the circuit board. Each first tab 340 is attached to the electrically conductive lid 330 and/or the circuit board 310.

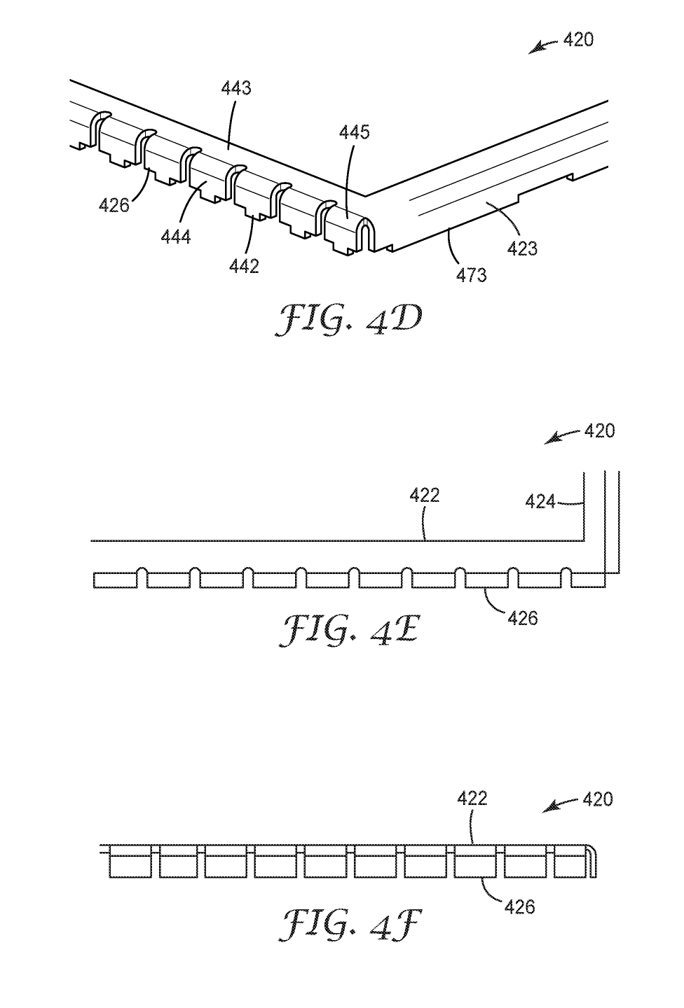

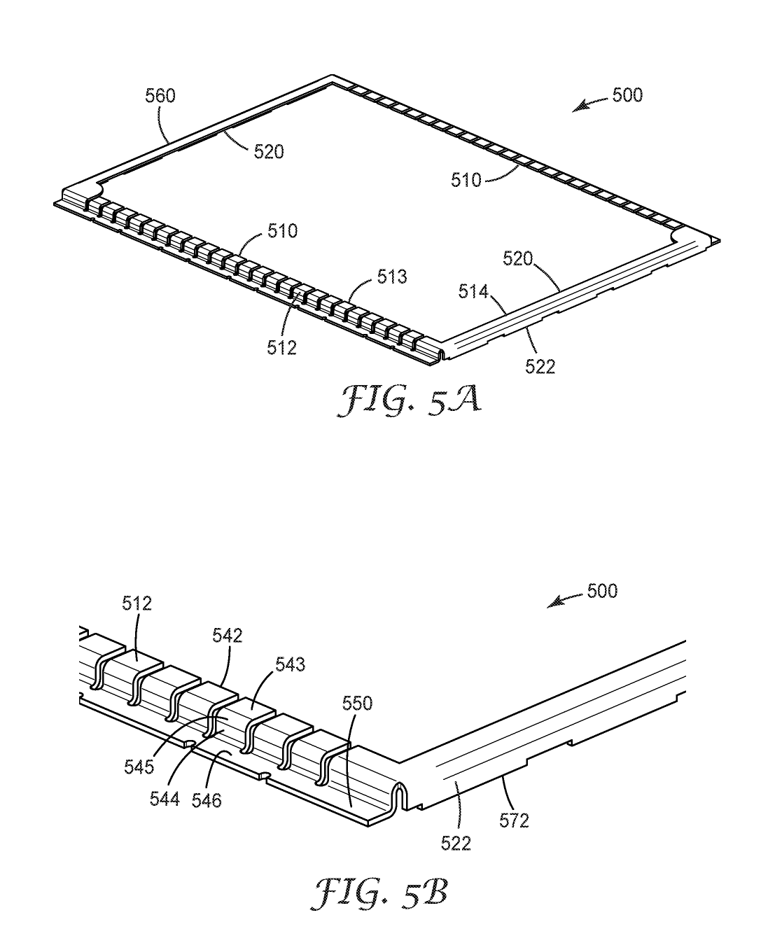

FIG. 4A illustrates a curved shield fence 410 in accordance with embodiments described herein. The shield fence 410 has first sides 412 arranged on a first portion of the perimeter of the shield fence 410 and second sides 414 arranged along a second portion of the perimeter of the shield fence 410. First sides 412 have a plurality of spaced apart first tabs 416. The second sides 414 have a plurality of spaced apart second tabs 418. According to various implementations, the first tabs 416 are narrower in width than the second tabs 418 along the axis parallel to the circuit board.

According to various implementations, the system includes a shield fence that is bendable and/or is flexible. FIG. 4B shows a shield fence 420 that can be bendable and/or flexible in accordance with various embodiments. Similarly as in FIG. 4A, the shield fence 420 includes first parallel sides 422 arranged on a first portion 428 of the perimeter 429 of the shield fence 420 and second parallel sides 424 arranged along a second portion 427 of the perimeter 429 of the shield fence 420. First parallel sides 422 have a plurality of spaced apart first tabs 426. Second parallel sides 424 have a plurality of spaced apart second tabs 423. While FIG. 4B shows that the shield fence 420 has a generally rectangular shape, it is to be understood that the shield fence may be of any shape. For example, the shield fence may have a general shape of a hexagon, and/or a circle.

FIG. 4C illustrates a side view of one of the first sides of a shield fence 420 in accordance with some implementations. As described above, the shield fence 420 has a plurality of first tabs 426 that are separated by open spaces 434. According to various embodiments, the open spaces 434 ay have substantially equal widths between each of the first tabs 440. In some embodiments, at least some of the open spaces may have different widths that other open spaces.

FIG. 4D illustrates a more detailed perspective view of a portion of the shield fence 420 having a plurality of first tabs 426 on the first side 422 of the shield fence 420. Each first tab 426 includes a horizontal portion 443 substantially parallel to the circuit board. Each first tab 426 includes a vertical portion 444 that is substantially perpendicular to the circuit board. Each of the first tabs 426 may be the same width as other first tabs or at least some of the first tabs may have a different width than other first tabs. The vertical portion 444 terminates at the free end 442 of the first tab 426. The free end 442 of each first tab 426 may have a different width than the rest of the vertical portion 444. For example, FIG. 4D shows that the free end 442 of the first tab 426 is narrower than the vertical portion 444. In some cases the free end 442 of the first tab 426 has the same width as the rest of the vertical portion 444. Each first tab 426 includes an elbow portion 445 that joins the horizontal portion 443 to the vertical portion 444. According to various implementations, the horizontal portion 443 of the first tab 426 is attached to the electrically conductive lid and/or the circuit board. In some embodiments, one of the horizontal portions 443 and vertical portions 444 of each first tab 426 is attached to the electrically conductive lid and the other of the horizontal portions 443 and vertical portions 444 of the first tab 426 is attached to the circuit board.

FIG. 4D also shows at least one second tab 423 on a second side 424 of the shield fence 420. In some implementations, the second tabs 423 are wider than at least one of the first tabs. The second tabs 446 may be wider than all of the first tabs in some embodiments. The perimeter of the shield fence may be a polygon having a plurality of sides. The plurality of spaced apart first tabs 426 may be arranged along one side 422 of the perimeter 429 and the plurality of spaced apart second tabs 423 may be arranged along an adjacent side 424 of the perimeter 429.

FIGS. 4E and 4F illustrate top and side views, respectively, of the first tabs 426 described in conjunction with FIGS, 4A-4D. FIG. 4E shows the top view of a portion of shield fence 420 having a first side 422 and a second side 424. The first side 422 includes a plurality of spaced apart first tabs 426 along the perimeter 429. FIG. 4F illustrates a side view of a portion of the shield fence 420 having a plurality of spaced apart first tabs 426 along the perimeter 429 of the first side 422 of the shield fence 420.

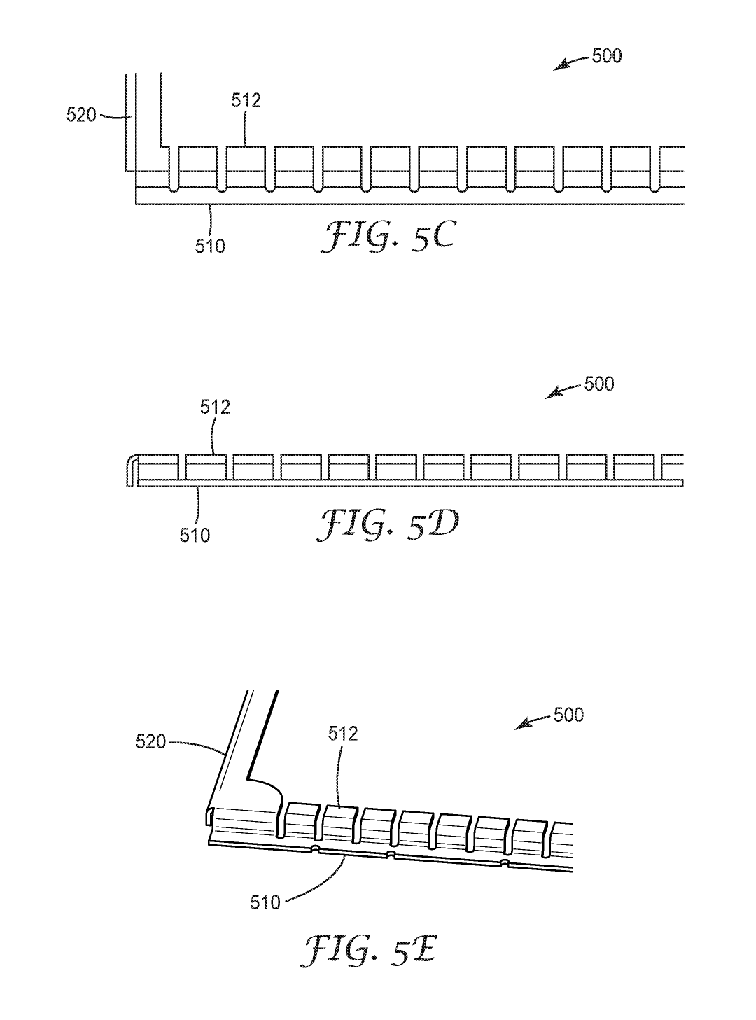

FIGS. 5A-5E show shield fence 500 that is bendable and/or flexible in accordance with various embodiments. FIG. 5A illustrates a shield fence 500 having first parallel sides 510 arranged on a first portion 513 of the perimeter 560 of the shield fence 500 and second parallel sides 520 arranged along a second portion 514 of the perimeter 560 of the shield fence. The first sides 510 have spaced apart first tabs 512. The second sides 520 have spaced apart second tabs 522. While FIG. 5A shows that the shield fence 500 has a generally rectangular shape, it is to be understood that a shield fence may be of any shape. In some cases, at least one of the first sides 510 and second sides 520 is generally L-shaped. According to various implementations, each of the first 510 and second 520 sides is generally L-shaped. In some cases the first sides 510 are generally S-shaped and the second sides 520 are generally L-shaped. The second sides 520 may be generally S-shaped and the first sides are generally L-shaped. Each of the first sides 510 and the second sides 520 may be generally S shaped in some configurations.

FIG. 5B illustrates a more detailed view the shield fence 500 of FIG. 5A. The shield fence 500 has a plurality of first tabs 512. Each first tab 512 includes at least one horizontal portion 543, 546 substantially parallel to the circuit board. Each first tab 512 includes a vertical portion 544 that is substantially perpendicular to the circuit board. Each of the first tabs 512 may have the same width along the axis parallel to the circuit board or one or more of the first tabs may have a different with than other first tabs. Each of the first tabs 512 may include a top horizontal portion 543 that is substantially parallel to the circuit board. In some cases, the top horizontal portion 543 terminates at the free end 542 of the first tab 512. A bottom horizontal portion 546 may be joined to the top horizontal portion 543 by a vertical portion 544 that is substantially perpendicular to the circuit board and an elbow portion 545 that joins the top horizontal 543 portion to the vertical portion 544. According to various implementations, the top horizontal portion 543 is attached to the electrically conductive lid and the bottom horizontal portion 546 is attached to the circuit board.

According to various implementations, the bottom horizontal portion 546 is an elongated continuous portion extending continuously along the first portion 513 of the perimeter 560 of the shield fence 500 parallel to the circuit board. Each first tab 512 extends from the elongated continuous horizontal portion 546 of the shield fence, such that one of the elongated continuous portion 546 of the shield fence and the plurality of first tabs 512 is attached to the electrically conductive lid. The other of the elongated continuous portions 546 of the fence 500 and the plurality of first tabs 512 are attached to the circuit board.

In some cases, the shield fence further includes a plurality of spaced apart second tabs 522 arranged along a second portion 514 of the perimeter 560 of the shield fence 500. Each second tab 522 terminates at a free end 572. In some cases, the first tabs 512 are narrower than the second tabs 522.

FIGS. 5C and 5D illustrate different views of the first tabs 512 described in conjunction with FIGS, 5A and 5B. FIG. 5C shows a top view of a shield fence 500 having a first side 510 and a second side 520. The first side 510 includes a plurality of spaced apart first tabs 512 along the perimeter 560. FIG. 5D illustrates a side view of a shield fence 500 having a plurality of spaced apart first tabs 512 along the perimeter 560 of the first side 510 of the shield fence 500. FIG. 5E shows a different view of a shield fence 500 in conjunction with FIGS. 5A-5D. A first side 510 of the shield fence 500 has first tabs 512 spaced apart along the perimeter 560 of the first side 510. A second side 520 may have second tabs spaced apart along the perimeter 560 of the second side 520.
Item 1. A system comprising:

a curved circuit board

at least one electronic component mounted on the circuit board and electrically connected to a first electrically conductive trace of the circuit board;

an electrically conductive curved fence conformably attached to the circuit board and surrounding the at least one electronic component, the fence electrically connected to a different second electrically conductive trace of the circuit board; and

an electrically conductive lid conformably attached to a top side of the fence and covering the at least one electronic component, wherein the fence comprises a plurality of spaced apart first tabs arranged along at least a first portion of a perimeter (429,560) of the fence, each first tab having a free end and attached to the electrically conductive lid or the circuit board.
Item 2. The system of item 1, wherein the curved circuit board is rigid.
Item 3. The system of any of items 1 through 2, wherein the curved circuit board has a shape of a partial cylinder.
Item 4. The system of any of items 1 through 3 comprising a plurality of electronic components mounted on the circuit board, surrounded by the electrically conductive curved fence, and covered by the electrically conductive lid.
Item 5. The system of any of items 1 through 4, wherein each first tab comprises:

a horizontal portion substantially parallel to the circuit board;

a vertical portion substantially perpendicular to the circuit board; and

an elbow portion joining the horizontal portion to the vertical portion, the horizontal portion of the tab attached to the electrically conductive lid or the circuit board.
Item 6. The system of item 5, wherein the horizontal portion terminates at the free end of the tab.
Item 7. The system of item 5, wherein the vertical portion terminates at the free end of the tab.
Item 8. The system of item 5, wherein one of the horizontal and vertical portions of each tab is attached to the electrically conductive lid and the other of the horizontal and vertical portions of the tab is attached to the circuit board.
Item 9. The system of any of items claim 1 through 5, wherein the curved fence comprises an elongated continuous portion extending continuously along the first portion of the perimeter of the curved fence parallel to the circuit board, each first tab extending from the continuous horizontal portion of the fence, such that one of the elongated continuous portion of the fence and the plurality of first tabs is attached to the electrically conductive lid and the other of the elongated continuous portion of the fence and the plurality of first tabs is attached to the circuit board.
Item 10. The system of any of items 1 through 5, wherein each first tab comprises:

a top horizontal portion substantially parallel to the circuit board;

a bottom horizontal portion substantially parallel to the circuit board; and

a vertical portion joining the top and bottom horizontal portions and substantially perpendicular to the circuit board, the top horizontal portion attached to the electrically conductive lid and the bottom horizontal portion attached to the circuit board.
Item 11. The system of any of items 1 through 10, wherein the fence further comprises a plurality of spaced apart second tabs arranged along a different second portion of the perimeter of the fence, each second tab terminating at a free end, the first tabs being narrower than the second tabs.
Item 12. The system of item 11, wherein the perimeter of the fence is a polygon having a plurality of sides, wherein the plurality of spaced apart first tabs are arranged along one side of the perimeter, and the plurality of spaced apart second tabs are arranged along an adjacent side of the perimeter.
Item 13. A flexible rectangular metal fence for conformably mounting on a curved circuit board and surrounding an electronic component mounted on the circuit board, the fence comprising opposing parallel first sides and opposing parallel second sides, wherein each first side comprises a plurality of spaced apart narrower first tabs and each second side comprises a plurality of spaced apart wider second tabs, each first and second tab having a free end.
Item 14. The flexible rectangular metal fence of item 13, wherein at least one of the first and second sides is generally L-shaped.
Item 15. The flexible rectangular metal fence of any of items 13 through 14, wherein each of the first and second sides is generally L-shaped.
Item 16. The flexible rectangular metal fence of any of items 13 through 14, wherein the first sides are generally S-shaped and the second sides are generally L-shaped.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

Various modifications and alterations of the embodiments discussed above will be apparent to those skilled in the art, and it should be understood that this disclosure is not limited to the illustrative embodiments set forth herein. The reader should assume that features of one disclosed embodiment can also be applied to all other disclosed embodiments unless otherwise indicated. It should also be understood that all U.S. patents, patent applications, patent application publications, and other patent and non-patent documents referred to herein are incorporated by reference, to the extent they do not contradict the foregoing disclosure.

1-10 (canceled)

11. A system comprising:
a curved circuit board;
at least one electronic component mounted on the circuit board and electrically connected to a first electrically conductive trace of the circuit board;
an electrically conductive curved fence conformably attached to the circuit board and surrounding the at least one electronic component, the fence electrically connected to a different second electrically conductive trace of the circuit board; and
an electrically conductive lid conformably attached to a top side of the fence and covering the at least one electronic component, wherein the fence comprises a plurality of spaced apart first tabs arranged along at least a first portion of a perimeter of the fence, each first tab having a free end and attached to the electrically conductive lid or the circuit board.

12. The system of claim 11, wherein the curved circuit board is rigid.

13. The system of claim 11, wherein the curved circuit board has a shape of a partial cylinder.

14. The system of claim 11 comprising a plurality of electronic components mounted on the circuit board, surrounded by the electrically conductive curved fence, and covered by the electrically conductive lid.

15. The system of claim 11, wherein each first tab comprises:
a horizontal portion substantially parallel to the circuit board;
a vertical portion substantially perpendicular to the circuit board; and
an elbow portion joining the horizontal portion to the vertical portion, the horizontal portion of the tab attached to the electrically conductive lid or the circuit board.

16. The system of claim 15, wherein the horizontal portion terminates at the free end of the tab.

17. The system of claim 15, wherein the vertical portion terminates at the free end of the tab.

18. The system of claim 15, wherein one of the horizontal and vertical portions of each tab is attached to the electrically conductive lid and the other of the horizontal and vertical portions of the tab is attached to the circuit board.

19. The system of claim 11, wherein the curved fence comprises an elongated continuous portion extending continuously along the first portion of the perimeter of the curved fence parallel to the circuit board, each first tab extending from the continuous horizontal portion of the fence, such that one of the elongated continuous portion of the fence and the plurality of first tabs is attached to the electrically conductive lid and the other of the elongated continuous portion of the fence and the plurality of first tabs is attached to the circuit board.

20. The system of claim 11, wherein each first tab comprises:
a top horizontal portion substantially parallel to the circuit board;
a bottom horizontal portion substantially parallel to the circuit board; and
a vertical portion joining the top and bottom horizontal portions and substantially perpendicular to the circuit board, the top horizontal portion attached to the electrically conductive lid and the bottom horizontal portion attached to the circuit board.

21. The system of claim 11, wherein the fence further comprises a plurality of spaced apart second tabs arranged along a different second portion of the perimeter of the fence, each second tab terminating at a free end, the first tabs being narrower than the second tabs.

22. The system of claim 21, wherein the perimeter of the fence is a polygon having a plurality of sides, wherein the plurality of spaced apart first tabs are arranged along one side of the perimeter, and the plurality of spaced apart second tabs are arranged along an adjacent side of the perimeter.

23. A flexible rectangular metal fence for conformably mounting on a curved circuit board and surrounding an electronic component mounted on the circuit board, the fence comprising opposing parallel first sides and opposing parallel second sides, wherein each first side comprises a plurality of spaced apart narrower first tabs and each second side comprises a plurality of spaced apart wider second tabs, each first and second tab having a free end.

24. The flexible rectangular metal fence of claim 23, wherein at least one of the first and second sides is generally L-shaped.

25. The flexible rectangular metal fence of claim 23, wherein each of the first and second sides is generally L-shaped.

26. The flexible rectangular metal fence of claim 23, wherein the first sides are generally S-shaped and the second sides are generally L-shaped.
